(19) United States
(12) Patent Application Publication
(10) Pub. No.: US 2026/0259262 A1
(43) Pub. Date: Sep. 3, 2026

(54) EFFICIENT SCANNABLE REGISTER FILE CELL WITH LOW OVERHEAD

(71) Applicant: International Business Machines Corporation, Armonk, NY (US)

(72) Inventors: Michael LEE, Austin, TX (US); Elizabeth L. GERHARD, Rochester, MN (US)

(21) Appl. No.: 19/066,977

(22) Filed: Feb. 28, 2025

(51) Int. Cl. G01R 31/3185

(52) U.S. Cl. CPC G01R 31/318536; G01R 31/318541; G01R 31/318552

(57) ABSTRACT

Techniques for performing a scan test of an integrated circuit with multiple efficient scannable memory cells are described. An example method includes loading first test scan content into a first scannable memory cell of a scan chain including scannable memory cells arranged in an array. A scan test is performed on the scan chain. The scan test involves controlling, via a first test clock signal, the first scannable memory cell to overwrite content of a second scannable memory cell of the scan chain with the first test scan content. The first scannable memory cell is adjacent to the second scannable memory cell within the scan chain. The second scannable memory cell is clocked by the first test clock signal. The first scannable memory cell is clocked by a second test clock signal different from the first test clock signal.

### BACKGROUND

The present invention relates to electronic circuits, and more specifically to a scannable memory cell in integrated circuits.

Scan tests are often performed during integrated circuit testing and/or for debugging purposes. A scan test generally refers to an approach in which (i) storage elements of an integrated circuit are connected as a scan chain, (ii) a scan vector is scanned in through the scan chain, (iii) the integrated circuit is placed in an evaluation mode for one or more clock cycles, and (iv) the values stored due to evaluation are compared with an expected output to determine whether the integrated circuit is operating as desired or not.

To support both scan tests and normal mode operations of an integrated circuit, additional circuitry (e.g., scan circuitry) is often provided within the integrated circuit for each storage element that is designed to be a part of a scan chain and normal mode operations. This additional circuitry generally enables the bits of the scan vector to be received and stored in the storage element during the scan operations, and the bits from a portion of the integrated circuit during normal mode operations to be used according to the topology/connectivity with which the integrated circuit is designed. The storage element along with the additional circuitry provided for the storage element may be together be referred to as a memory cell.

### SUMMARY

One embodiment described herein is a scannable register. The scannable register includes a plurality of scannable memory cells arranged in an array. Each of the plurality of scannable memory cells includes: a first inverter and a second inverter cross-coupled with the first inverter; a first scan access transistor coupled to the first and second inverters; and a second scan access transistor coupled to the first and second inverters. For a first scannable memory cell of the plurality of scannable memory cells, the first and second scan access transistors of the first scannable memory cell are clocked by a first test clock signal. For a second scannable memory cell of the plurality of scannable memory cells adjacent to the first scannable memory cell: the first and second scan access transistors of the second scannable memory cell are clocked by a second test clock signal different from the first test clock signal; and the first and second scan access transistors of the second scannable memory cell are coupled to the first and second inverters of the first scannable memory cell.

Another embodiment described herein is a scannable register. The scannable register includes a plurality of scannable memory cells arranged in an array. Each of the plurality of scannable memory cells includes: a first inverter and a second inverter cross-coupled with the first inverter; a first scan access transistor coupled to the first and second inverters; and a second scan access transistor coupled to the first and second inverters. For a first scannable memory cell of the plurality of scannable memory cells, the first and second scan access transistors of the first scannable memory cell are clocked by a first test clock signal. For a second scannable memory cell of the plurality of scannable memory cells adjacent to the first scannable memory cell: the first and second scan access transistors of the second scannable memory cell are clocked by a second test clock signal different from the first test clock signal; and the first and second scan access transistors of the second scannable memory cell are coupled to the first and second inverters of the first scannable memory cell. The scannable register also includes a latch coupled to the second scannable memory cell.

Another embodiment described herein is a method for performing a scan test of an integrated circuit. The method includes loading first test scan content into a first scannable memory cell of a scan chain comprising a plurality of scannable memory cells arranged in an array. The method also includes performing a scan test on the scan chain. Performing the scan test includes controlling, via a first test clock signal, the first scannable memory cell to overwrite content of a second scannable memory cell of the scan chain with the first test scan content. The first scannable memory cell is adjacent to the second scannable memory cell within the scan chain. The second scannable memory cell is clocked by the first test clock signal. The first scannable memory cell is clocked by a second test clock signal different from the first test clock signal.

Other embodiments include, without limitation, a computer program product that includes a storage medium having computer-readable program code that enables a processing unit to implement one or more aspects of the disclosed methods as well as a system having a processor, memory, and application programs configured to implement one or more of the disclosed methods.

### BRIEF DESCRIPTION OF THE DRAWINGS

FIG. 1 is a block diagram of a computing environment, according to certain embodiments.

FIG. 2 illustrates an example conventional scannable memory cell with additional scan circuitry.

FIG. 3 illustrates an example scannable memory cell implemented without (or at least reduced) additional scan circuitry, according to certain embodiments.

FIG. 4 illustrates an example portion of an array cell structure that may be included within a register file, according to certain embodiments.

FIG. 5 illustrates an example configuration of a scan chain and overflow latch that may be included within a register file, according to certain embodiments.

FIG. 6 illustrates an example timing diagram of alternating test clock signals for controlling an array structure of scannable memory cells, according to certain embodiments.

FIG. 7 is a flowchart of an example method for performing a scan test of an IC, according to certain embodiments.

### DETAILED DESCRIPTION

Some of the memory cells in certain integrated circuits (ICs) may include additional circuitry (e.g., scan circuitry) that allows the memory cells to function as “scan cells” (e.g., stimulus and observation points) during an IC's evaluation mode (e.g., IC testing and/or debugging) and to perform their intended functional role during the IC's normal operation. However, while including such additional circuity within a memory cell can make that cell scannable, this additional circuitry comes at the cost of increasing the overall circuitry overhead of the memory cell. In many instances, there is typically an overhead of doubling the circuitry of each memory cell within the IC in order to make that cell scannable. For example, there is an added transistor count (e.g., the number of transistors typically doubles per memory cell) as well as an increase in the corresponding additional interconnects per memory cell in conventional approaches that include such additional circuitry in order to support scannable memory cells. In addition to the increased circuitry overhead, there is typically a related cost in increased chip area consumed by such additional circuitry.

Certain embodiments described herein provide an efficient scannable memory cell (e.g., scannable register file cell) with low overhead that allows for an IC to be implemented in an evaluation mode (or scan mode) (e.g., for IC testing and/or debugging purposes) and in an operational mode (or normal mode). As described in greater detail herein, certain embodiments provide an array cell structure in which a scan test (during an evaluation mode of the IC) uses adjacent memory cells in the existing data memory block to provide the scan path, as opposed to using a separate scan memory block (e.g., additional circuitry) to provide the scan path. Within the existing data memory block, scan access transistors (e.g., scan pass gates of the scan access transistors) are coupled to the complementary outputs of each cross-coupled memory element. The scan access transistors are controlled by one of two test clock signals, test clock signal A (ACLK) and test clock signal B (BCLK), where ACLK is connected to every odd-indexed cell location and BCLK is connected to every even-indexed cell location.

In certain embodiments, a first portion of a scan-based test (e.g., first pass of the scan-based test) is performed using the array cell structure based on BCLK. In such embodiments, the scan-based test uses BCLK to overwrite the data of each even-indexed cell with the data of the respective odd-indexed cell adjacent to the even-indexed cell and to read out each odd-indexed cell's data from the respective even-indexed cells with scannable memory accesses. Stated differently, the scan test uses BCLK to write each odd-indexed cell's data into the adjacent (higher) even-indexed cell location and to read out the data.

Additionally or alternatively, in certain embodiments, a second portion of the scan-based test (e.g., second pass of the scan-based test) is performed using the array cell structure based on ACLK. In such embodiments, the scan-based test uses ACLK to overwrite the data of each odd-indexed cell (except for an initial odd-indexed cell of a scan chain) with the data of the respective even-indexed cell adjacent to the odd-indexed cell and to read out each even-indexed cell's data from the respective odd-indexed cells with scannable memory accesses. Stated differently, the scan test uses ACLK to write each even-indexed cell's data (except for a highest even-indexed cell at the end of a scan chain) into the adjacent (higher) odd-indexed cell location and to read out the data. For the highest even-indexed cell at the end of the scan chain, the scan test uses ACLK to write the highest even-indexed cell's data into an overflow latch adjacent to the highest even-indexed cell. For example, since the scan path within the array cell structure uses alternating A and B clocked elements, the array cell structure may include an additional overflow latch at the end of the scan chain to capture the last (even) cell's scanned out content.

The efficient scannable memory cell design described herein may provide various technical advantages. For example, the efficient scannable memory cell design described herein leverages existing circuitry to convert non-scannable memory cells to scannable memory cells, allowing for implementing scannable memory cells with lower overhead (relative to IC designs that include additional scan circuitry within memory cells in order to make those cells scannable). Additionally, the efficient scannable memory cell design described herein can be implemented without additional (or at least a reduced amount of) clocking or testing complexities. Accordingly, the efficient scannable memory cell design described herein may allow for operating ICs with reduced power, reduced area, and/or increased performance, among other benefits.

Although the terms “first,” “second,” “third,” etc., may be used herein to describe various elements, components, regions, layers and/or sections, these elements, components, regions, layers and/or sections should not be limited by these terms. These terms may be only used to distinguish one element, component, region, layer or section from another element, component, region, layer, or section. Terms such as “first,” “second,” and other numerical terms, when used herein, do not imply a sequence or order unless clearly indicated by the context. Thus, a first element, component, region, layer, or section discussed herein could be termed a second element, component, region, layer, or section without departing from the teachings of the example embodiments.

As used herein, a hyphenated form of a reference numeral refers to a specific instance of an element and the un-hyphenated form of the reference numeral refers to the collective element. Thus, for example, device “12-1” refers to an instance of a device class, which may be referred to collectively as devices “12” and any one of which may be referred to generically as a device “12”.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as block 160, which includes test scan component 165 configured to perform a scan-based test using a scan path provided by adjacent memory cells of an existing data memory block. In addition to block 160, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 160, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

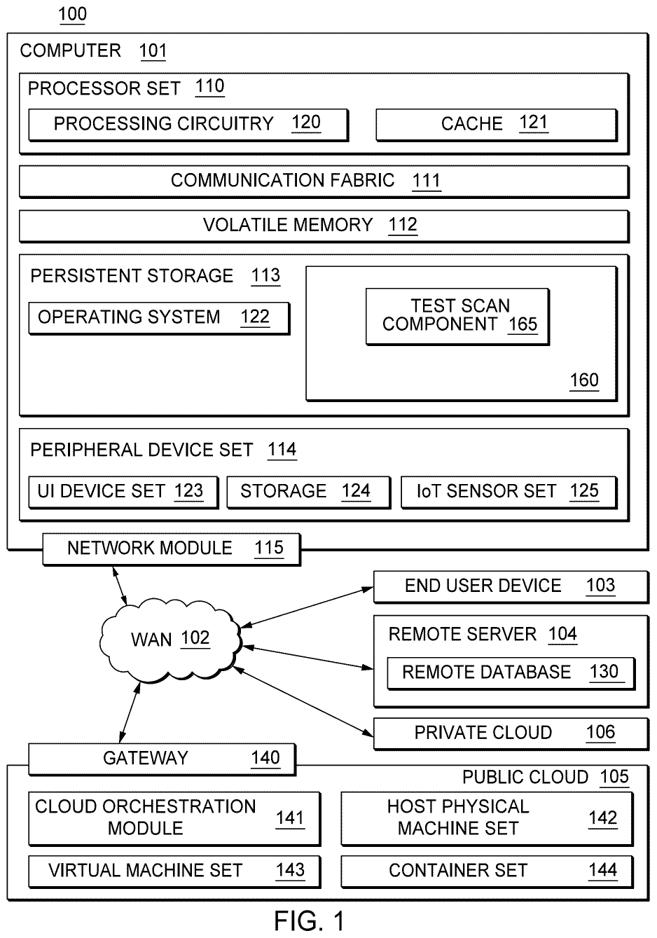

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 160 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM (SRAM). Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 160 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

Note, to clearly point out novel features of the present invention, the following discussion omits or only briefly describes conventional features of data processing systems which are apparent to those skilled in the art. It may be noted that a numbered element is numbered according to the figure in which the element is introduced, and is referred to by that number throughout succeeding figures. Additionally, as used herein, a hyphenated form of a reference numeral refers to a specific instance of an element and the un-hyphenated form of the reference numeral refers to the collective element. Thus, for example, device “12-1” refers to an instance of a device class, which may be referred to collectively as devices “12” and any one of which may be referred to generically as a device “12”.

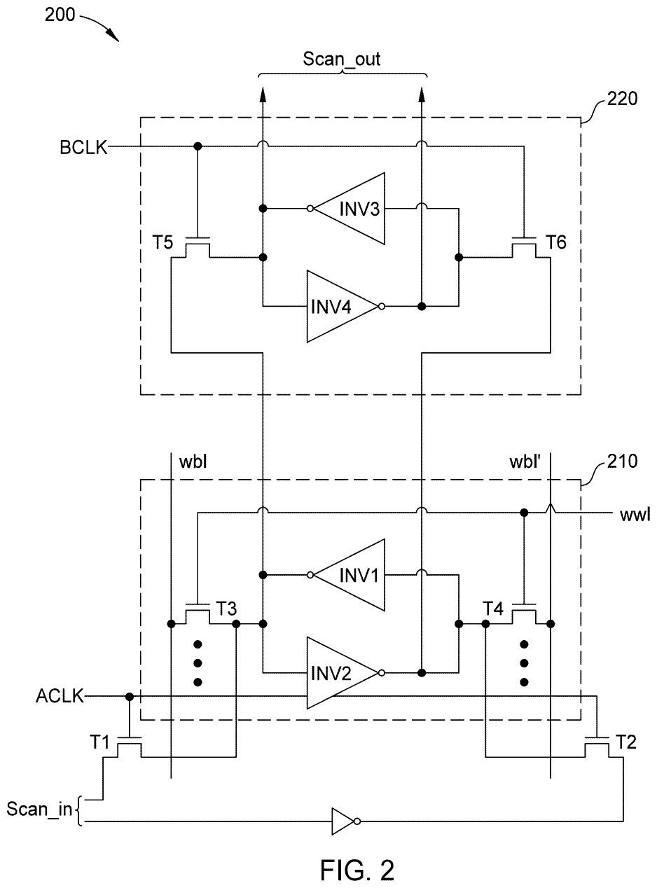

As noted, conventional techniques for making memory cells scannable generally involve including additional circuitry (e.g., scan circuitry) within the memory cell, such that the memory cell can function as a scan cell during an IC's evaluation mode and perform the cell's intended functional role during the IC's normal operation. The additional circuitry generally includes secondary latch circuitry that is activated when the IC is placed in an evaluation mode (or scan mode). The secondary latch circuitry may be coupled to primary latch circuitry, which feeds the activated secondary latch circuitry, forming a primary-secondary flip-flop. By way of example, FIG. 2 depicts a scannable memory cell 200 implemented with additional scan circuitry.

The scannable memory cell 200 is an example implementation of an SRAM cell with additional scan circuitry. As shown, the scannable memory cell 200 includes primary latch circuitry 210, secondary latch circuitry 220, and scan access transistors T1 and T2. The primary latch circuitry 210 includes cross-coupled inverters INV1 and INV2 and access transistors T3 and T4. In normal-mode operations of the scannable memory cell 200, the access transistors T3 and T4 are used to access the stored data in the cell 200. The access transistors T3 and T4 are turned ON/OFF by the control line, referred to as word line (wwl). The word line (wwl) thus can trigger read/write operations on the cell 200 via word bit line (wbl) and the complement of word bit line (wbl′).

The secondary latch circuitry 220 includes cross-coupled inverters INV3 and INV4 and access transistors T5 and T6. The access transistors T5 and T6 are coupled to the outputs of the cross-coupled inverters INV1 and INV2, respectively. The secondary latch circuitry 220 may be referred to as a “shadow latch” because it performs no function in the normal-mode operations of reading from and writing to the scannable memory cell 200. In a scan-operation of the scannable memory cell 200, scan-in data may be written into the primary latch circuitry 210 via the scan access transistors T1 and T2. A test clock signal A (ACLK) acts as a trigger for loading the scan-in data into the primary latch circuitry 210. A test clock signal B (BCLK) is used to capture scan-in data from the primary latch circuitry 210 into the secondary latch circuitry 220 via the access transistors T5 and T6. At a next clock cycle, the scan-in data may be output from the secondary latch circuitry 220 as scan-out data.

Because the secondary latch circuitry 220 has substantially the same component circuitry as the primary latch circuitry 210, the chip area used for the secondary latch circuitry 220 may be approximately the same as the chip area used for the primary latch circuitry 210. Consequently, scan methods that utilize conventional scannable memory cells, such as the scannable memory cell 200, within a register file may result in approximately doubling the chip area of the register file. For large register files and other large arrays of memory cells, this is a substantial cost.

To address this, certain embodiments described herein provide an efficient scannable memory cell (e.g., scannable register file cell) that leverages existing circuitry to convert a non-scannable memory cell into a scannable memory cell, allowing for implementing scannable memory cells with lower overhead relative to conventional scannable memory cells, such as the scannable memory cell 200. That is, the efficient scannable memory cell described herein may be implemented without (or at least with reduced) additional scan circuitry. In certain embodiments, the scannable memory cell described herein includes an array cell structure that uses adjacent memory cells in the existing data memory block to provide a scan path during an evaluation mode (or scan mode), as opposed to using a separate scan memory block to provide the scan path.

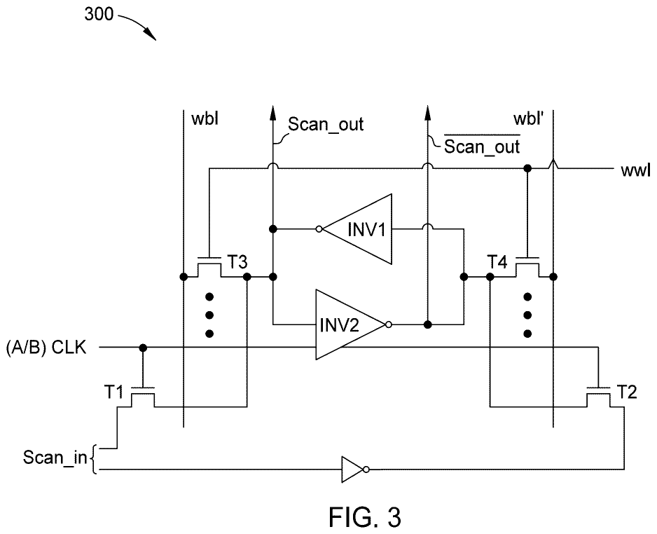

FIG. 3 illustrates an example scannable memory cell 300, according to certain embodiments. In certain embodiments, the scannable memory cell 300 is an illustrative example of a scannable memory cell (e.g., register file cell) that may be included in an array cell structure of multiple scannable memory cells. The array cell structure may be included within a register file. The features described with respect to the scannable memory cell 300 may be used in conjunction with other embodiments described herein. For example, the scannable memory cell 300 may be implemented within the computing environment 100 depicted in FIG. 1. For instance, the scannable memory cell 300 may be implemented within volatile memory 112, cache 121, among other storage.

Compared to the scannable memory cell 200, the scannable memory cell 300 is implemented without (or at least a reduced amount of) additional scan circuitry (e.g., secondary latch circuitry 220). As shown, the scannable memory cell 300 includes scan access transistors T1 and T2 (e.g., n-type metal-oxide-semiconductor (NMOS) transistors), cross-coupled inverters INV1 and INV2, and access transistors T3 and T4 (e.g., NMOS transistors). Although not shown, the cross-coupled inverters INV1 and INV2 may be implemented with two NMOS transistors for pull-down and two p-type metal-oxide-semiconductor (PMOS) transistors for pull-up. Two stable stage (logic ‘0’ and ‘1’) may be stored through the feedback loop between the NMOS and PMOS transistors.

The scan access transistor T1 is coupled to the output of cross-coupled inverter INV1, and the scan access transistor T2 is coupled to the complementary output of cross-coupled inverter INV2. In certain embodiments, the scan access transistors T1 and T2 are not active during normal-mode operations, since the scan-in functionality of the cell 300 is not used during normal-mode operations. As described in greater detail herein, depending on whether the scannable memory cell 300 is an even-indexed cell or an odd-indexed cell within an array cell structure of a scan chain, the scannable memory cell 300 may be clocked by a test clock signal A (ACLK) or a test clock signal B (BCLK). For example, the scannable memory cell 300 may be clocked by ACLK when the scannable memory cell 300 is an odd-indexed cell within a scan chain, and the scannable memory cell 300 may be clocked by BCLK when the scannable memory cell 300 is an even-indexed cell within a scan chain. In certain embodiments, when two scannable memory cells 300 are adjacent to each other, a first of the two scannable memory cells 300 may be used as a primary latch of a primary-secondary flip-flop, and a second of the two scannable memory cells 300 may be used as a secondary latch of the primary-secondary flip-flop, as further described herein.

Note, the transistors T1, T2, T3, and T4 may be implemented by a transmission gate or any of other various suitable components, such as a field-effect transistor (FET) (with a PMOS implementation or NMOS implementation), negative-positive-negative (NPN) transistor, or positive-negative-positive (PNP) transistor, as illustrative, non-limiting examples. In certain cases, the transistors T1, T2 may be controlled by ACLK or BCLK, which may be received from a controller/processor, such as a processor within processing circuitry 120.

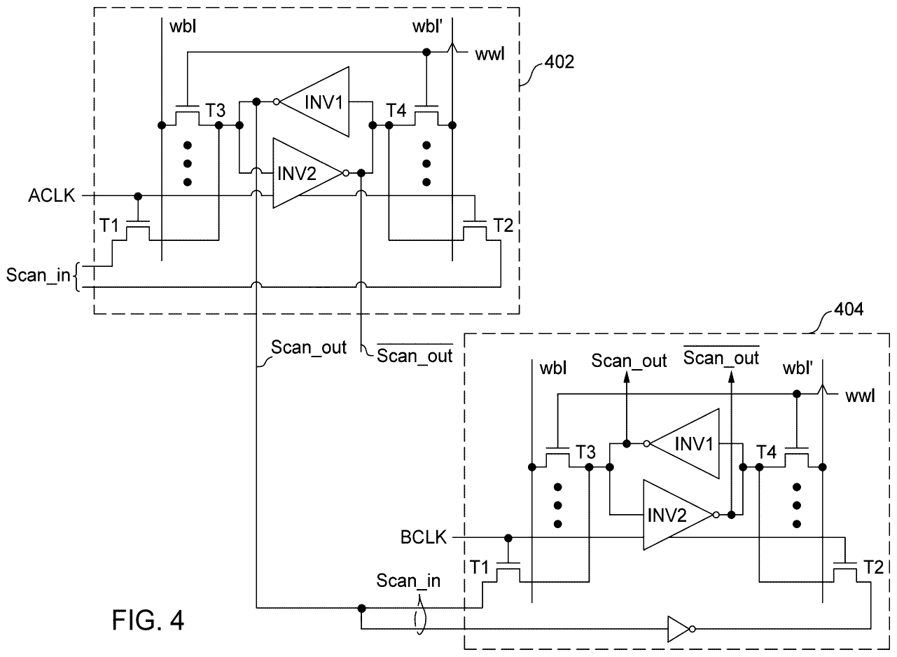

FIG. 4 depicts an example portion of an array cell structure that may be included within a register file, according to certain embodiments. Here, the array cell structure portion includes a scannable memory cell 402 and a scannable memory cell 404. Each of the scannable memory cells 402 and 404 is an illustrative implementation of the scannable memory cell 300 illustrated in FIG. 3.

As depicted in FIG. 4, the scannable memory cell 402 is clocked by ACLK, and the scannable memory cell 404 is clocked by BCLK. Alternating different test clock signals between cells 402 and 404 can significantly reduce the chip area occupied by each cell due to reduced wiring, e.g., since a single test clock signal is being fired over each cell as opposed to two test clock signals. In certain embodiments, when the scannable memory cell 402 is clocked by ACLK and the efficient scannable memory cell 402 is clocked by BCLK, the scannable memory cells 402 and 404 form a primary-secondary flip-flop. For example, the scannable memory cell 402 may function as the primary latch of the primary-secondary flip-flop, and the scannable memory cell 404 may function as the secondary latch of the primary-secondary flip-flop. In such a configuration, the scan input of the scannable memory cell 404 (e.g., via scan access transistors T1 and T2 of the scannable memory cell 404) may be coupled to the scan output of the scannable memory cell 402 (e.g., via the output of the cross-coupled inverter INV1 of the scannable memory cell 402), e.g., as shown in FIG. 4. The scan output of the scannable memory cell 402 may be left floating, e.g., as shown in FIG. 4. Note, in other embodiments, the scannable memory cell 402 may be clocked by BCLK, and the scannable memory cell 404 may be clocked by ACLK.

In certain embodiments, when the scannable memory cells 402 and 404 are in scan mode, the BCLK acts as a trigger for capturing the scan-in data from the scannable memory cell 402 (e.g., primary latch) into the scannable memory cell 404 (e.g., secondary latch). In this manner, the scannable memory cells 402 and 404 may be converted into a primary-secondary flip-flop during an evaluation mode (or scan mode) of an IC.

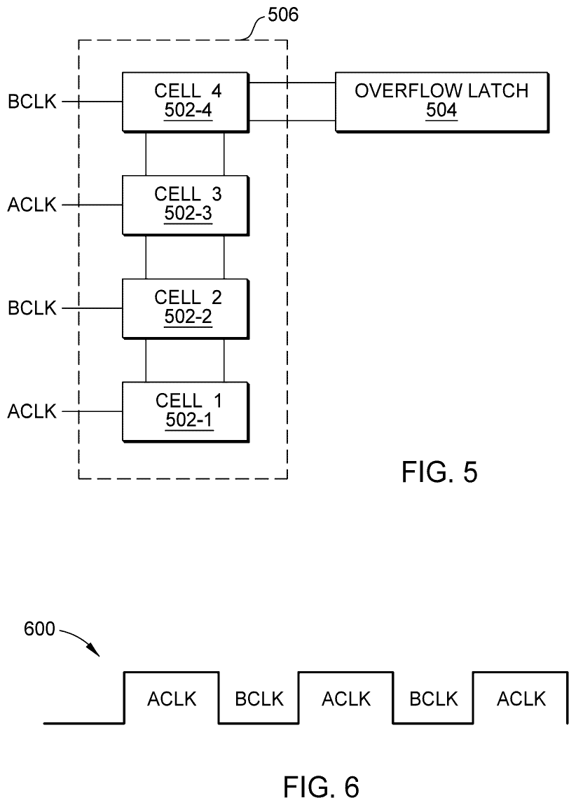

FIG. 5 illustrates an example configuration of a scan chain 506 and overflow latch 504 that may be included within a register file, according to certain embodiments. The features described with respect to FIG. 5 may be used in conjunction with other embodiments described herein. For example, the scan chain 506 and the overflow latch 504 may be implemented within the computing environment 100 depicted in FIG. 1. For instance, the scan chain 506 and the overflow latch 504 may be implemented within volatile memory 112, cache 121, among other storage.

The scan chain 506 includes an array cell structure with multiple connected scannable memory cells 502-1 to 502-4 (also referred to herein as scannable memory cells 502 1-4 or scannable memory cells 502). Within the array cell structure of scan chain 506, the indexes of the scannable memory cells 502 are in increasing (or ascending) order, such that scannable memory cell 502-1 is the lowest-indexed scannable memory cell and scannable memory cell 502-4 is the highest-indexed scannable memory cell. The overflow latch 504 is adjacent to scannable memory cell 502-4, which is located at the end of the scan chain 506 (e.g., the scannable memory cell 502-4 is the highest (even)-indexed scannable memory cell of the scan chain 506). Each of the scannable memory cells 502 is an illustrative implementation of the scannable memory cell 300 depicted in FIG. 3. In certain embodiments, in order to implement a scan chain with the scannable memory cells described herein, the total number of scannable memory cells 502 within the scan chain may be even. Here, for example, the scan chain 500 includes four scannable memory cells 502 1-4. Note, however, that although the scan chain 500 is depicted with four scannable memory cells 502 for conceptual clarity, the scan chain 500 may include any even number of scannable memory cells 502.

The cells 502 in FIG. 5 are clocked with alternating test clock signals ACLK and BCLK. In particular, the odd-indexed numbered cells (e.g., scannable memory cells 502-1 and 502-3) within the scan chain 500 are clocked with ACLK and the even-indexed numbered cells (e.g., scannable memory cells 502-2 and 502-4) within the scan chain 500 are clocked with BCLK. FIG. 6 illustrates a timing diagram 600 including the alternating test clock signals ACLK and BCLK, according to certain embodiments.

In certain embodiments, performing a scan test with the configuration depicted in FIG. 5 may involve scanning with BCLK to capture all the ACLK-connected cell content and to read out the ACLK-connected cell content. For example, when scanning with BCLK, the content of scannable memory cell 502-1 may be transferred to (or overwrite the content of) scannable memory cell 502-2, and the content of scannable memory cell 502-3 may be transferred to (or overwrite the content of) scannable memory cell 502-4. That is, when BCLK fires, scannable memory cells 502-2 and 502-4 open and capture the content of scannable memory cells 502-1 and 502-3, respectively.

Additionally or alternatively, in certain embodiments, performing a scan test with the configuration depicted in FIG. 5 may involve scanning with ACLK to capture all the BCLK-connected cell content and to read out the BCLK-connected cell content. For example, when scanning with ACLK, the content of scannable memory cell 502-2 may be transferred to (or overwrite the content of) scannable memory cell 502-3, and the content of scannable memory cell 502-4 may be transferred to (or overwrite the content of) the overflow latch 504. In certain embodiments, the overflow latch 504 may be used at the end of the scan chain 500 to capture the last cell's (e.g., scannable memory cell 502-4) BCLK-connected content. Although not shown, the overflow latch 504 may be clocked with ACLK. The overflow latch 504 may be implemented with a Set-Reset (S-R) latch, as an illustrative, non-limiting example. In certain embodiments, when ACLK fires, scannable memory cell 502-1, scannable memory cell 502-3, and overflow latch 504 open and capture the scan input for scannable memory cell 502-1, the content of scannable memory cell 502-2, and the content of scannable memory cell 502-4, respectively.

In certain embodiments, performing the scan-based test with the configuration depicted in FIG. 5 may involve (i) during a first portion of the scan test (e.g., first pass of the scan test), using BCLK to write every odd-indexed cell's data into the adjacent (higher) even-indexed cell location and to read out the data with scannable memory accesses and (ii) during a subsequent second portion of the scan test (e.g., second pass of the scan test), using ACLK to write every even-indexed cell's data into the adjacent (higher) odd-indexed cell location or an overflow latch (if the even-indexed cell is a last-indexed cell of the scan chain) and to read out the data with scannable memory accesses.

In certain embodiments, the even-indexed numbered cells'contents or the odd-indexed numbered cells'contents may be preserved depending on which of ACLK and BCLK fires first. For example, if ACLK is fired first, then the original contents of the odd-indexed numbered cells may be lost since the odd-indexed numbered cells may capture the even-indexed numbered cells'contents, as described herein. On the other hand, in another example, if BCLK is fired first, then the original contents of the even-indexed numbered cells may be lost since the even-indexed numbered cells may capture the odd-indexed numbered cells'contents. In certain embodiments, after ACLK/BCLK is fired, subsequent firings of ACLK/BCLK may keep pushing the data down the scan chain. For example, the initial BCLK may push the content of scannable memory cell 502-1 into scannable memory cell 502-2, the subsequent ACLK may push the content of scannable memory cell 502-2 into scannable memory cell 502-3, the subsequent BCLK may push the content of scannable memory cell 502-3 into scannable memory cell 502-4, and so on.

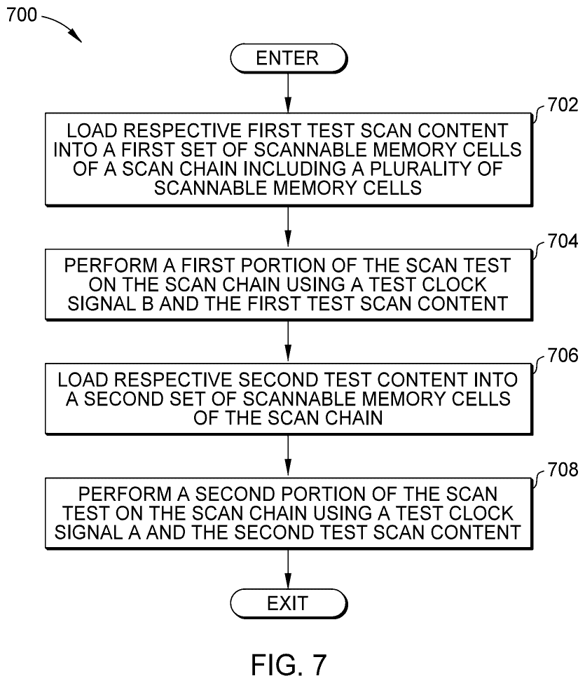

FIG. 7 is a flowchart of an example method 700 for performing a scan test of an IC, according to certain embodiments. Method 700 may be performed by processing circuitry (e.g., processing circuitry 120) executing test scan component 165. For example, the test scan component 165 may include logic (or computer executable code), that when executed by the processing circuitry, performs the method 700. In certain embodiments, one or more of the blocks depicted in method 700 may be performed while the IC is in an evaluation mode (or scan mode).

Method 700 may enter at block 702, where the processing circuitry loads respective first test scan content (e.g., first test scan data) into a first set of scannable memory cells of a scan chain (e.g., scan chain 506) including a plurality of scannable memory cells. The first set of scannable memory cells may include odd-indexed scannable memory cells (e.g., scannable memory cells 502-1 and 502-3) of the scan chain.

At block 704, the processing circuitry performs a first portion of the scan test on the scan chain using a test clock signal B (e.g., BCLK) and the first test scan content. In certain embodiments, performing the first portion of the scan test involves controlling, via the test clock signal B, the first set of scannable memory cells to (i) write the respective first test scan content (e.g., first test scan data) of each scannable memory cell within the first set of scannable memory cells into a respective adjacent (higher-indexed) scannable memory cell of a second set of scannable memory cells of the scan chain and (ii) read out the respective first test scan content from the adjacent scannable memory cell of the second set of scannable memory cells.

In certain embodiments, the first set of scannable memory cells includes odd-indexed scannable memory cells (e.g., scannable memory cells 502-1 and 502-3) of the scan chain, and the second set of scannable memory cells includes even-indexed scannable memory cells (e.g., scannable memory cells 502-2 and 502-4) of the scan chain. In such embodiments, the processing circuitry (at block 704) may use the test clock signal B to, for each even-indexed scannable memory cell, overwrite the content of the even-indexed scannable memory cell with the respective first test scan content of an adjacent lower odd-indexed scannable memory cell. Using scan chain 500 as an illustrative example, the content of scannable memory cell 502-2 may be overwritten with the content of scannable memory cell 502-1, and the content of scannable memory cell 502-4 may be overwritten with the content of scannable memory cell 502-3.

At block 706, the processing circuitry loads respective second test scan content (e.g., second test scan data) into a second set of scannable memory cells of the scan chain. The second set of scannable memory cells may include even-indexed scannable memory cells (e.g., scannable memory cells 502-2 and 502-4) of the scan chain.

At block 708, the processing circuitry performs a second portion of the scan test on the scan chain using a test clock signal A (e.g., ACLK) and the second test scan content. In certain embodiments, performing the second portion of the scan test involves controlling, via the test clock signal A, the second set of scannable memory cells to (i) for each scannable memory cell within the second set of scannable memory cells located prior to the end of the scan chain, write the respective second test scan content (e.g., second test scan data) of the scannable memory cell into a respective adjacent (higher-indexed) scannable memory cell of the first set of scannable memory cells of the scan chain, (ii) for the scannable memory cell within the second set of scannable memory cells located at the end of the scan chain, write the respective second test scan content of the scannable memory cell into an overflow latch (e.g., overflow latch 504), and (iii) read out the respective second test scan content from the adjacent scannable memory cell of the first set of scannable memory cells and the overflow latch.

In certain embodiments, the first set of scannable memory cells includes odd-indexed scannable memory cells (e.g., scannable memory cells 502-1 and 502-3) of the scan chain, and the second set of scannable memory cells includes even-indexed scannable memory cells (e.g., scannable memory cells 502-2 and 502-4) of the scan chain. In such embodiments, the processing circuitry (at block 708) may use the second test clock signal to (i) for each odd-indexed scannable memory cell (except an initial odd-indexed scannable memory cell of the scan chain, such as scannable memory cell 502-1), overwrite the content of the odd-indexed scannable memory cell with the respective second test scan content of an adjacent lower even-indexed scannable memory cell and (ii) overwrite the content of the overflow latch with the content of the last (highest) even-indexed scannable memory cell of the scan chain. Using scan chain 500 as an illustrative example, the content of scannable memory cell 502-3 may be overwritten with the content of scannable memory cell 502-2, and the content of overflow latch 504 may be overwritten with the content of scannable memory cell 502-4.

Advantageously, the efficient scannable memory cell described herein has a significantly lower circuit overhead compared to conventional scannable memory cells implemented with additional circuitry. For example, compared to eight transistors per conventional scannable memory cell, the efficient scannable memory cell described herein may have a circuit overhead of two transistors for the write port to support the “scan in” into the cell.

While the foregoing is directed to embodiments of the present invention, other and further embodiments of the invention may be devised without departing from the basic scope thereof, and the scope thereof is determined by the claims that follow.

What is claimed is:

1. A scannable register comprising:
a plurality of scannable memory cells arranged in an array, each of the plurality of scannable memory cells comprising:
a first inverter and a second inverter cross-coupled with the first inverter;
a first scan access transistor coupled to the first and second inverters; and
a second scan access transistor coupled to the first and second inverters, wherein:
for a first scannable memory cell of the plurality of scannable memory cells, the first and second scan access transistors of the first scannable memory cell are clocked by a first test clock signal; and
for a second scannable memory cell of the plurality of scannable memory cells adjacent to the first scannable memory cell:
the first and second scan access transistors of the second scannable memory cell are clocked by a second test clock signal different from the first test clock signal; and
the first and second scan access transistors of the second scannable memory cell are coupled to the first and second inverters of the first scannable memory cell.

2. The scannable register of claim 1, wherein:
the first scannable memory cell is an odd-indexed scannable memory cell within the plurality of scannable memory cells; and
the second scannable memory cell is an even-indexed scannable memory cell within the plurality of scannable memory cells.

3. The scannable register of claim 2, wherein the first scannable memory cell is configured to overwrite content of the second scannable memory cell in response to the second test clock signal.

4. The scannable register of claim 3, wherein an index of the first scannable memory cell within the plurality of scannable memory cells is lower than an index of the second scannable memory cell within the plurality of scannable memory cells.

5. The scannable register of claim 2, wherein the second scannable memory cell is configured to overwrite content of the first scannable memory cell in response to the first test clock signal.

6. The scannable register of claim 5, wherein an index of the first scannable memory cell within the plurality of scannable memory cells is higher than an index of the second scannable memory cell within the plurality of scannable memory cells.

7. The scannable register of claim 1, wherein a total number of the plurality of scannable memory cells is even.

8. The scannable register of claim 1, wherein:
the first test clock signal is connected to every odd-indexed scannable memory cell of the plurality of scannable memory cells; and
the second test clock signal is connected to every even-index scannable memory cell of the plurality of scannable memory cells.

9. A scannable register comprising:
a plurality of scannable memory cells arranged in an array, each of the plurality of scannable memory cells comprising:
a first inverter and a second inverter cross-coupled with the first inverter;
a first scan access transistor coupled to the first and second inverters; and
a second scan access transistor coupled to the first and second inverters, wherein:
for a first scannable memory cell of the plurality of scannable memory cells, the first and second scan access transistors of the first scannable memory cell are clocked by a first test clock signal; and
for a second scannable memory cell of the plurality of scannable memory cells adjacent to the first scannable memory cell:
the first and second scan access transistors of the second scannable memory cell are clocked by a second test clock signal different from the first test clock signal; and
the first and second scan access transistors of the second scannable memory cell are coupled to the first and second inverters of the first scannable memory cell; and
a latch coupled to the second scannable memory cell.

10. The scannable register of claim 9, wherein the latch is clocked by the first test clock signal.

11. The scannable register of claim 10, wherein:
the first scannable memory cell is an odd-indexed scannable memory cell within the plurality of scannable memory cells; and
the second scannable memory cell is an even-indexed scannable memory cell within the plurality of scannable memory cells.

12. The scannable register of claim 11, wherein the first scannable memory cell is configured to overwrite content of the second scannable memory cell in response to the second test clock signal.

13. The scannable register of claim 11, wherein the second scannable memory cell is configured to overwrite content of the latch in response to the first test clock signal.

14. The scannable register of claim 9, wherein the second scannable memory cell is a highest-indexed cell within the plurality of scannable memory cells.

15. A method for performing a scan test of an integrated circuit, the method comprising:
loading first test scan content into a first scannable memory cell of a scan chain comprising a plurality of scannable memory cells arranged in an array; and
performing a scan test on the scan chain, comprising controlling, via a first test clock signal, the first scannable memory cell to overwrite content of a second scannable memory cell of the scan chain with the first test scan content, wherein:
the first scannable memory cell is adjacent to the second scannable memory cell within the scan chain;
the second scannable memory cell is clocked by the first test clock signal; and
the first scannable memory cell is clocked by a second test clock signal different from the first test clock signal.

16. The method of claim 15, further comprising loading second test scan content into the second scannable memory cell of the scan chain, wherein performing the scan test on the scan chain further comprises controlling, via the second test clock signal, the second scannable memory cell to overwrite content of a third scannable memory cell of the scan chain with the second test scan content.

17. The method of claim 15, further comprising loading second test scan content into the second scannable memory cell of the scan chain, wherein performing the scan test on the scan chain further comprises controlling, via the second test clock signal, the second scannable memory cell to overwrite content of a latch coupled to the second scannable memory cell with the second test scan content.

18. The method of claim 17, wherein the second scannable memory cell is a highest-indexed memory cell of the scan chain.

19. The method of claim 15, wherein:
the first scannable memory cell is an odd-indexed scannable memory cell of the scan chain; and
the second scannable memory cell is an even-indexed scannable memory cell of the scan chain.

20. The method of claim 15, wherein a total number of the plurality of scannable memory cells is even.
